(19) United States
(12) Patent Application Publication
(10) Pub. No.: US 2026/0351517 A1
(43) Pub. Date: Nov. 5, 2026

(54) CAPACITIVELY COUPLED PLASMA PROCESSOR

(71) Applicant: ADVANCED MICRO-FABRICATION EQUIPMENT INC. CHINA, Shanghai (CN)

(72) Inventors: Yichuan ZHANG, Shanghai (CN); Rubin YE, Shanghai (CN)

(21) Appl. No.: 19/123,574

(22) PCT Filed: Oct. 23, 2023
(86) PCT No.: PCT/CN2023/125906

§ 371 Date: Apr. 23, 2025

(30) Foreign Application Priority Data
Nov. 1, 2022 (CN) 202211357656.X

(51) Int. Cl. H01J 37/32

(52) U.S. Cl. CPC H01J 37/32091; H01J 37/32183; H01J 37/32972

(57) ABSTRACT

Provided is a capacitively coupled plasma processor, including a reaction chamber including a base and an upper electrode provided opposite to the base. The base is configured to support a substrate to be processed. A source RF power source and a biased RF power source are connected to the base. A radio frequency signal processing device is connected to a unidirectional coupler at a source radio frequency power output end to detect base frequency reflection power reflected to a high-frequency RF power source. The radio frequency signal processing device includes a radio frequency power detector, a fast Fourier transform module, and a processor. The processor receives a first reflection power value outputted by the radio frequency power detection module and power proportion parameters of frequencies obtained from the fast Fourier transform module and calculates a second reflection power value without the intermodulation reflection power according to a preset algorithm.

### CROSS-REFERENCE TO RELATED APPLICATIONS

This application is a national stage of International Application No. PCT/CN2023/125906, filed on Oct. 23, 2023, which claims priority to and the benefit of Chinese Patent Application No. 202211357656.X, filed on Nov. 1, 2022. Both of the aforementioned applications are hereby incorporated by reference in their entireties.

### TECHNICAL FIELD

The present disclosure relates to the technical field of semiconductor equipment, and in particular to a plasma processor and a radio frequency matching method thereof.

### BACKGROUND

In the technical field of semiconductor manufacturing, plasma etching is an important process where a wafer is processed. With the update of the requirements on semiconductor devices, it is usually needed to supply a plurality of radio frequency power to a plasma processor. The capacitively coupled plasma processor shown in FIG. 1 includes a reaction chamber 10. The interior of the chamber includes an upper electrode 24 and a base 20 as a lower electrode. An electrostatic chuck 22 for fixing a wafer W thereon is arranged above the base 20. A high-frequency RF power source HF supplies high-frequency (fH) radio frequency power to the base through a matching circuit 11 as source radio frequency power to enter the plasma processor to ignite and maintain plasma. One low-frequency RF power source LF supplies low-frequency (fL) radio frequency power to the base through a matching circuit 13 to control ion energy incident to the wafer. The radio frequencies outputted by the two radio frequency power supplies can be maximized supplied into the reaction chamber 10 as the matching circuits 13 and 11 work, so as to minimize the reflection power. For part of applications needed to rapidly switch the output power, typically when a pulse-type radio frequency power output is needed, it is further needed to adjust the output frequencies of the radio frequency power supplies. By rapidly adjusting the frequencies of the outputted RF power, impedance matching can be performed at a microsecond level to realize rapid impedance matching of the pulse-type radio frequency power.

Performing impedance matching by way of adjusting the output frequencies of the RF power source needs to precisely detect the radio frequency power reflected to the RF power source from the reaction chamber, but the reflected radio frequency power cannot be rapidly and precisely detected in the prior art. In the prior art, a radio frequency signal and a noise signal needed to be detected after filtering by a filter usually, finally the reflection power signal is detected. However, for an RF power source with a large frequency variation range, the filter not only needs to exclude the noise frequency signal, but also allows fH with a very large frequency range to pass with low resistivity. This problem cannot be solved through a conventional solution of selecting a group of inductors and capacitors with optimized parameters to form a special parameter filter. Therefore, it is needed to develop a novel detection device or method to rapidly and precisely detect the reflection power in the plasma reaction chamber. The detection method can be suitable for effectively filter radio frequencies in noise frequency bands except for the forward frequency while rapidly changing the output frequency within a certain range.

### SUMMARY

The present disclosure provides a capacitively coupled plasma processor, including a reaction chamber, where the reaction chamber internally includes a base and an upper electrode provided opposite to the base, and the base is configured to support a substrate to be processed; a first RF power source outputs first forward power with a first frequency to the base to ignite or maintain plasma in the reaction chamber, and a second RF power source outputs second forward power with a second frequency to the base, the first frequency being greater than 13 MHz and the second frequency being greater than 10 KHz and less than 400 KHz, where a radio frequency processing device is connected between a first RF power source output end and the base; the radio frequency signal processing device includes a sampling device, a radio frequency power detection module, a fast Fourier transform module, and a processor, where the radio frequency power detection module is configured to detect a reflection power signal obtained on the sampling device, the reflection power signal comprises reflection power with the first frequency and intermodulation reflection power with the first frequency±the second frequency, and the radio frequency power detection module obtains a first reflection power value according to the reflection power signal; the fast Fourier transform module performs decomposition to obtain power proportion parameters of the frequencies according to the reflection power signal; the processor receives the first reflection power value outputted by the radio frequency power detection module and the power proportion parameters of the frequencies obtained from the fast Fourier transform module, and calculates a second reflection power value without the intermodulation reflection power according to a preset algorithm; and the first RF power source adjusts the outputted first frequency according to the second reflection power value to realize impedance matching.

The preset algorithm includes: calculating a power proportion sum within the first frequency±extending frequency range according to the power proportion parameters provided by the fast Fourier transform module and calculating and obtaining the second reflection power value, the extending frequency being less than ½ of the second frequency. The preset algorithm includes: determining dividing frequencies fd1 and fd2 corresponding to the lowest power point between the first frequency signal and two intermodulation reflection signals, calculating a power proportion sum within the fd1-fd2 range, and calculating and obtaining the second reflection power value. According to the above algorithm, the reflection power of the base frequency can be precisely detected, so that effective matching is realized according to precise reflection power data.

### BRIEF DESCRIPTION OF THE DRAWINGS

In order to describe the technical solution of the present disclosure more clearly, the drawings needed in the description will be introduced briefly below. It is apparent that the drawings described below are one embodiment of the present disclosure, those of ordinary skill in the art further can obtain other drawings according to those drawings without making creative efforts.

FIG. 1 is a schematic structural diagram of a plasma processing device in the prior art;

FIG. 2a and FIG. 2b are schematic diagrams of first and second embodiments of the processing device of the present disclosure; and

FIG. 3 is a schematic diagram of a reflection power spectrum obtained after fast Fourier transform in the present disclosure.

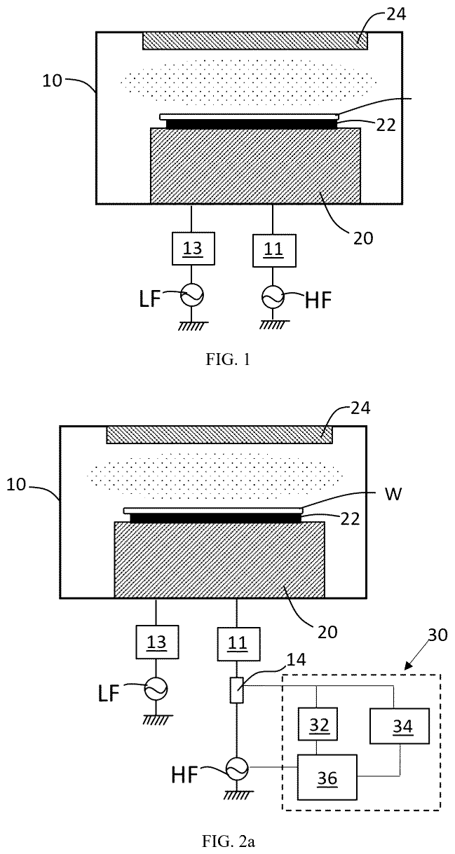

### DETAILED DESCRIPTION OF THE EMBODIMENTS

The technical solutions in the embodiments of the present disclosure will be clearly and intactly described below in combination with the drawings in the embodiments of the disclosure. Apparently, the embodiments described are only some embodiments, rather than all embodiments of the present disclosure. Based on the embodiments of the present disclosure, all other embodiments obtained by those ordinarily skilled in the art without creative work shall fall within the protection scope of the present disclosure.

It is found by the inventor through research that the primary reason causing detection distortion of a high-frequency radio frequency signal fH outputted by a RF power source is as follows: when high-frequency radio frequency power HF and low-frequency radio frequency power LF are simultaneously applied to the plasma processor, plasma will be generated. The plasma with nonlinear impedance will cause two radio frequency signals to generate an intermodulation effect, which enables the high-frequency signal reflected back to the RF power source HF to further have two intermodulation reflection frequency signals with frequencies of fH±fL besides the reflection power with base forward frequency fH. Moreover, according to calculation, compared with the forward frequency (fH) signal, the magnitudes of power of the two intermodulation reflection frequency signals can reach about 5-20%, which cannot be ignored. If the two intermodulation reflection frequency signals cannot be effectively eliminated, the subsequent algorithm which realizes radio frequency matching by adjusting the base frequency (fH) outputted by the RF power source HF will have a huge error, so that rapid matching cannot be realized rapidly and effectively. In the prior art, 2 MHz low-frequency radio frequency power (fL) is usually used. When the base frequency fH of the output frequency of the RF power source HF are relatively great, for example, 60 MHz, the two base frequencies are intermodulated in the plasma to obtain 58 MHz and 62 MHz and can be filtered from the reflection power signal by the filter. However, when the frequency outputted by the low-frequency RF power source LF is an ultra-low-frequency, that is, fL is only 10-400 KHz, the difference between the intermodulated frequencies 59.6 MHz and 60.4 MHz and the base forward frequency 60 MHz is extremely small, so that the intermodulated frequencies cannot be separated by filtering.

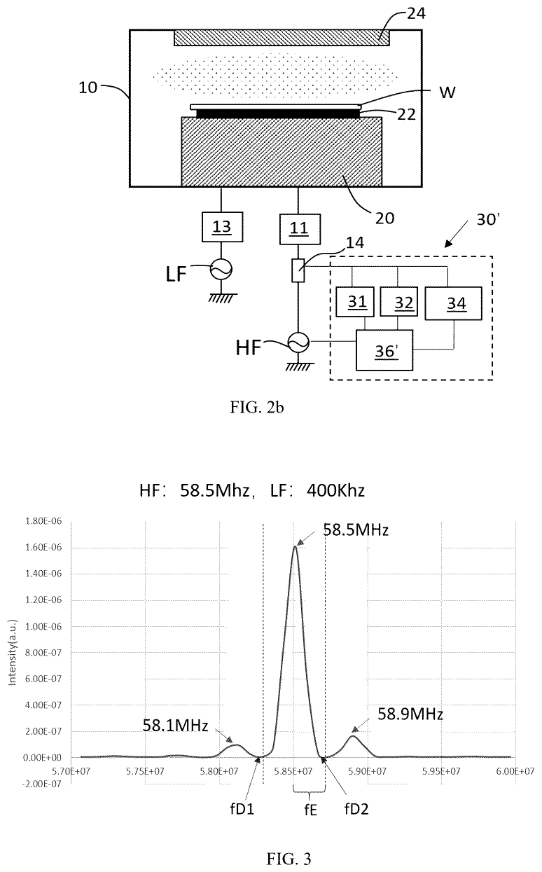

The present disclosure provides a novel high-frequency radio frequency signal matching control circuit shown in FIG. 2a according to the above discovery. The radio frequency power outputted by the high-frequency RF power source HF which can output the frequency in a variable frequency manner is outputted to a matcher 11 through a unidirectional coupler 14 and is finally fed into a plasma processing chamber 10 to form plasma for plasma processing. A radio frequency signal processing device 30 is connected to the unidirectional coupler 14 to detect base frequency reflection power reflected to a high-frequency radio fluency power supply. The radio frequency signal processing device 30 includes a radio frequency power detector 32, a fast Fourier transform module 34, and a processor 36. The radio frequency power detector 32 is connected to the unidirectional coupler 14 to detect the radio frequency power reflected by the plasma processor to reach the unidirectional coupler 14. A filter is provided in the matching circuit or between the RF power source HF and the base 20. A conduction frequency of the filter is subject to the radio frequency power outputted by the variable frequency high-frequency RF power source HF capable of passing through within the variable frequency range. For example, the output frequency of fH needs to be adjusted within a range of a center frequency 60 MHz±3 MHz, i.e., the output range of the high-frequency RF power source changes between 57 MHz and 63 MHz, so that the filter is designed to enable signals in this frequency band to pass with low resistivity. fH may also be another frequency, for example, it may be 27 Mhz. By means of parameter settings of the filter, signals within the frequency range of about 5% around the center frequency can pass with low resistivity, and signals with other frequencies are blocked. By providing the filter, the power detected by the radio frequency power detector 32 will be around base frequency as a core to prevent other frequency signals such as harmonic signals from interfering with power detection. Therefore, the radio frequency power detector 32 can detect the filtered first reflection power signal in the frequency band of 57-63 MHz, and the power value of the first reflection power signal can be acquired by detection. The first reflection power signal is mixed with the base frequency fH signal and corresponding intermodulation frequency signals fH±fL.

Moreover, a fast Fourier transform module 34 is also connected to the output end of the unidirectional coupler 14, and spectrum power distribution data of the filtered signal can be sampled and rapidly calculated. FIG. 3 shows an exemplary spectrum power distribution diagram when fL is 400 KHz.

The power intensity of the intermodulation reflection frequency is related to the output power of the low-frequency radio frequency source LF. When the output power of LF is increased, signal intensities of the two intermodulation reflection frequencies 59.6 MHz and 60.4 MHz in FIG. 3 will be correspondingly increased.

One processor 36 simultaneously receives the output signals from the radio frequency power detector 32 and the fast Fourier transform module 34. According to the proportion of the base frequency (fH) in fast Fourier transform data, i.e., the ratio of the area of a 58.5 MHz peak in the area of all frequency peaks in the figure, the processor 36 can calculate the power intensity of the signal corresponding to the base frequency 58.5 MHz in the reflection power detected by the radio frequency power detector 32 in the first reflection power signal base frequency. For calculating the power proportion corresponding to the base frequency, as can be shown in FIG. 3, an extending frequency fE is set. The power within the fH±fE frequency range is set as the reflection power corresponding to the base frequency fH, where the extending frequency fE can be a half less than fL to ensure that the intermodulation reflection frequency signals are excluded. For example, the extending frequency fE in FIG. 3 is 0.2 MHz, the sum of the power proportions within the range of 58.3-58.7 MHz is 85%, and in this case, the power corresponding to the base frequency 58.5 MHz in the reflection power is 85% of the first reflection power value. Or, two points with lowest power between the base frequency fH and the two intermodulation reflection frequency fH±fL peaks can further be calculated according to a power distribution curve in FIG. 3. Frequencies fD1 and fD2 corresponding to the two points with lowest power serve as two division frequencies. The sum of the power proportions corresponding to the frequency band between the two division frequencies is multiplied by the detected first reflection power value to obtain the optimized second reflection power. For example, fD1 and fD2 are respectively 58.25 MHz and 58.68 Mhz. The sum of the proportions within the range of the two crossover frequencies is 85.5%, and the power corresponding to the base frequency 58.5 MHz in the reflection power is 85.5% of the first reflection power value.

The above frequency band separation or calculation method is merely an example. Other algorithms can be selected according to specific demands and application as long as the signals representing the intermodulation reflection frequencies can be removed. Other algorithms also belong to the embodiment of the present disclosure.

The processor 36 multiplies the received first reflection power value with the power proportion corresponding to the base frequency to obtain the second reflection power value, the second reflection power value corresponding to the base frequency in the first reflection power value without the intermodulation frequency power. Finally, the second reflection power value is fed back to the high-frequency RF power source HF, and the high-frequency RF power source HF can adjust the frequency through a multi-step processing within predetermined frequency range according to the received precise reflection power value, so that the output frequency of the high-frequency RF power source HF is successively optimized to finally reach the optimal matching state. With the change of the output frequency fH of the high-frequency RF power source HF, spectrum component of the base frequency fH detected by the corresponding radio frequency power detector 32 and the fast Fourier transform module 34 will change correspondingly. The processor 36 can identify current base frequency according to the outputted base frequency signal from the high-frequency RF power source HF or the fH frequency signal detected by an additional detector. Then the processor 36 can calculate the power ratio of current base frequency power to the reflection powerbase frequency. Then the processor 36 calculates the correspondingly second reflection power value from the current first reflection power value, and provides the second reflection power value to the high-frequency RF power source HF, so that the high-frequency RF power source HF can perform a next matching operation to adjust the output frequency fH in the next step, and this cycle is repeated till the matching state is reached.

Sampling of the reflection power signal in the present disclosure is realized by the unidirectional coupler 14, so that the forward radio frequency power and the reflection radio frequency power are separated. The radio frequency signal at the output end of the RF power source can also be directly sampled digitally, and after AD conversion, the digitalized signal is processed by a computer. In the signal processing procedure, voltage and current phase differences of the forward radio frequency signal and the reflection radio frequency signal can be separated to respectively calculate the forward power and the reflection power value mixed with the base frequency fH and the intermodulation reflection frequency fH±fL. Then, the power portion corresponding to the base frequency in the reflection radio frequency signal is calculated through the fast Fourier transform module 34 proposed in the present disclosure, and finally, the second reflection power value without the intermodulation reflection frequency needed by radio frequency matching can be acquired.

The output frequency of the low-frequency RF power source LF in the present disclosure can be 10-300 KHz, and this low-frequency signal is more suitable for the reflection power detection device and detection method proposed in the present disclosure.

With the adoption of the radio frequency signal processing device 30 proposed in the present disclosure, the reflection power value of the base frequency reflected from the plasma processor can be detected more rapidly and precisely without designing the filter with restricted parameters. Moreover, the sampling and calculating speeds of fast Fourier transform can reach the microsecond level and even nanosecond level, which is higher than the corresponding speed in the frequency tuning step of the high-frequency RF power source HF itself, so that it can be guaranteed that the high-frequency RF power source can realize frequency tuning matching at the highest speed.

The present disclosure further provides another embodiment shown in FIG. 2b, where the radio frequency signal processing device 30′ includes a second radio frequency power detector 31 connected to one of the output ends of the unidirectional coupler 14 to detect a power value Pf of a radio frequency signal with the base frequency fH outputted by the RF power source HF. In combination with the radio frequency power detector 32, the Fast Fourier transform module 34, and the processor 36′ shown in FIG. 2a, the base frequency forward power Pf and the second reflection power can be completely detected through the radio frequency signal processing device 30′, and a plasma processor manufacturer can customize the optimized matching algorithm through the matching frequency algorithm built in the processor 36′ and the value is directly assigned to the high-frequency RF power source HF, so that the high-frequency RF power source HF directly outputs the frequency appointed by the processor 36′. By applying the radio frequency signal processing device 30′, matching algorithm preset by a RF power source supplier or RF system hardware difference will not affect RF signal detecting accuracy, so that the consistency of performance of the same algorithm in different matchers can be improved, and the development difficulty of the novel plasma processor is reduced. The processor 36′ in the present disclosure stores a frequency modulation matching program, and this embodiment where the matching program is integrated into the processor 36′ can greatly reduce the design difficulty of the high-frequency RF power source HF, which also improves the designing flexibility of the matching program.

The above is only the specific embodiments of the present disclosure and is not intended to limit the scope of protection of the present disclosure. Any modification or substitution apparent to those skilled in the art within the technical scope disclosed by the present disclosure shall fall within the scope of protection of the present disclosure. Therefore, the scope of protection of the present disclosure shall be subject to the scope of protection of the claims.

1. A capacitively coupled plasma processor, comprising:
a reaction chamber comprising:
a base configured to support a substrate to be processed, and
an upper electrode provided opposite to the base;
a first radio frequency (RF) power source configured to output a first forward power with a first frequency to the base to ignite or maintain plasma in the reaction chamber;
a second RF power source configured to output a second forward power with a second frequency to the base, the first frequency being greater than 13 Mhz and the second frequency being greater than 10 Khz and less than 400 Khz;
a radio frequency signal processing device is connected between an output end of the first RF power source and the base, the radio frequency signal processing device comprising:
a sampling device,
a radio frequency power detector configured to detect a reflection power signal obtained on the sampling device, wherein the reflection power signal comprises a reflection power with the first frequency and intermodulation reflection powers with the first frequency+the second frequency and the first frequency−the second frequency, and the radio frequency power detector is configured to obtain a first reflection power value according to the reflection power signal,
a fast Fourier transformer configured to perform a decomposition to obtain power proportion parameters of frequencies including the first frequency and the second frequency according to the reflection power signal, and
a processor configured to receive the first reflection power value outputted by the radio frequency power detector and the power proportion parameters of the frequencies obtained from the fast Fourier transformer, and to calculate a second reflection power value without the intermodulation reflection powers according to a preset algorithm,
wherein the first RF power source is configured to adjust an outputted first frequency according to the second reflection power value to achieve an impedance matching.

2. The capacitively coupled plasma processor according to claim 1, wherein the preset algorithm comprises:
calculating a power proportion sum within a range from the first frequency−an extending frequency to the first frequency+an extending frequency according to the power proportion parameters provided by the fast Fourier transformer, and
calculating and obtaining the second reflection power value, the extending frequency being less than ½ of the second frequency.

3. The capacitively coupled plasma processor according to claim 1, wherein the preset algorithm comprises:
determining division frequencies including a first division frequency (fd1) and a second division frequency (fd2) corresponding to points with a lowest power between a first frequency signal and two intermodulation reflection signals, and
calculating a power proportion sum within a range from fd1 to fd2, and
calculating and obtaining the second reflection power value.

4. The capacitively coupled plasma processor according to claim 1, wherein the sampling device includes at least one unidirectional coupler.

5. The capacitively coupled plasma processor according to claim 1, wherein the processor is configured to receives a first frequency numerical value and a first forward power value signal outputted by the first RF power source by a conducting circuit.

6. The capacitively coupled plasma processor according to claim 1, wherein the radio frequency power detector is further configured to detect a first forward power and output the first forward power to the processor.

7. The capacitively coupled plasma processor according to claim 1, wherein the processor is further configured to stores a matched frequency calculation program and calculates a corrected first frequency value corresponding to a next adjusting operation according to the second reflection power value and a first forward power value, and the first RF power source is configured to modify the outputted first frequency as the corrected first frequency value.

8. The capacitively coupled plasma processor according to claim 1, wherein the first frequency has a center frequency and a variation range with an amplitude being ±5% of the center frequency and further comprises a filter circuit provided between the first RF power source and the base, and the filter circuit is configured to enable radio frequency signals at the center frequency and within the variation range to pass through with a low resistance and block signals at other frequencies from passing through.

9. The capacitively coupled plasma processor according to claim 1, wherein a matching circuit is further connected in series between the first RF power source and the base.

10. The capacitively coupled plasma processor according to claim 1, wherein the second frequency is greater than 10 Khz and less than 300 Khz.

11. A capacitively coupled plasma processor, comprising:
a reaction chamber comprising:
a base configured to support a substrate to be processed; and
an upper electrode provided opposite to the base;
a first radio frequency (RF) power source configured to output a first forward power with a first frequency to the base to ignite or maintain plasma in the reaction chamber, wherein the first frequency is configured to be adjusted within a variable frequency range;
a second RF power source configured to output a second forward power with a second frequency to the base, wherein the reaction chamber is configured to reflects a reflection power signal to the first RF power source; the first frequency is greater than 13 Mhz and the second frequency is less than 10 Khz and less than 400 Khz;
a radio frequency signal processing device connected between an output end of the first RF power source and the base; the radio frequency signal processing device comprising:
a radio frequency power detector configured to detect the reflection power signal and obtain a first reflection power value;
a fast Fourier transformer configured to perform a decomposition to obtain power proportion parameters corresponding to the first frequency in the reflection power signal according to the reflection power signal; and
a processor configured to calculate the first reflection power value and the power proportion parameters corresponding to the first frequency to obtain a second reflection power value corresponding to the first frequency in the reflection power signal; and
wherein the first RF power source is configured to adjust an outputted first frequency according to the second reflection power value to achieve an impedance matching.

12. The capacitively coupled plasma processor according to claim 11, wherein, to obtain a second reflection power value corresponding to the first frequency in the reflection power signal, the processor is configured to:
calculate a power proportion sum within a range from the first frequency-an extending frequency to the first frequency+an extending frequency according to the power proportion parameters provided by the fast Fourier transformer, and
calculate and obtain the second reflection power value, the extending frequency being less than ½ of the second frequency.

13. The capacitively coupled plasma processor according to claim 11, wherein, to obtain a second reflection power value corresponding to the first frequency in the reflection power signal, the processor is configured to:
determine division frequencies including a first division frequency (fd1) and a second division frequency (fd2) corresponding to points with a lowest power between a first frequency signal and two intermodulation reflection signals, and
calculate a power proportion sum within a range from fd1 to fd2, and
calculate and obtain the second reflection power value.

14. The capacitively coupled plasma processor according to claim 11, wherein the sampling device includes at least one unidirectional coupler.

15. A method of achieving an impedance matching in a capacitively coupled plasma processor, comprising:
outputting, by a first radio frequency (RF) power source, a first forward power with a first frequency to a base to ignite or maintain plasma in a reaction chamber, wherein the capacitively coupled plasma processor comprises a reaction chamber comprising the base configured to support a substrate to be processed, and an upper electrode provided opposite to the base;
outputting, by a second RF power source, a second forward power with a second frequency to the base, the first frequency being greater than 13 Mhz and the second frequency being greater than 10 Khz and less than 400 Khz; and
detecting, by a radio frequency power detector of a radio frequency signal processing device, a reflection power signal obtained on a sampling device of the radio frequency signal processing device, wherein the reflection power signal comprises a reflection power with the first frequency and intermodulation reflection powers with the first frequency+the second frequency and the first frequency−the second frequency, the radio frequency signal processing device connected between an output end of the first RF power source and the base;
obtaining, by the radio frequency power detector, a first reflection power value according to the reflection power signal, performing, by a fast Fourier transformer of the radio frequency signal processing device, a decomposition to obtain power proportion parameters of frequencies including the first frequency and the second frequency according to the reflection power signal, and
receiving, by a processor of the radio frequency signal processing device, the first reflection power value outputted by the radio frequency power detector and the power proportion parameters of the frequencies obtained from the fast Fourier transformer;
calculating, by the processor, a second reflection power value without the intermodulation reflection powers according to a preset algorithm; and
adjusting, by the first RF power source, an outputted first frequency according to the second reflection power value to achieve the impedance matching.

16. The method according to claim 15, wherein the calculating, by the processor, the second reflection power value without the intermodulation reflection powers according to the preset algorithm comprises:
calculating a power proportion sum within a range from the first frequency−an extending frequency to the first frequency+an extending frequency according to the power proportion parameters provided by the fast Fourier transformer; and
calculating and obtaining the second reflection power value, the extending frequency being less than ½ of the second frequency.

17. The method according to claim 15, wherein the calculating, by the processor, the second reflection power value without the intermodulation reflection powers according to the preset algorithm comprises:
determining division frequencies including a first division frequency (fd1) and a second division frequency (fd2) corresponding to points with a lowest power between a first frequency signal and two intermodulation reflection signals;
calculating a power proportion sum within a range from fd1 to fd2; and
calculating and obtaining the second reflection power value.

18. The method according to claim 15, wherein the sampling device includes at least one unidirectional coupler.
